(19) United States
(12) Patent Application Publication
(10) Pub. No.: US 2024/0392474 A1
(43) Pub. Date: Nov. 28, 2024

(54) GROUP 13 ELEMENT NITRIDE SINGLE CRYSTAL SUBSTRATE, SUBSTRATE FOR EPITAXIAL GROWTH LAYER FORMATION, LAMINATE, AND EPITAXIAL SUBSTRATE FOR SEMICONDUCTOR DEVICE

(71) Applicant: NGK INSULATORS, LTD., Nagoya-shi (JP)

(72) Inventors: Kentaro NONAKA, Gifu-shi (JP); Takahiro TAMURA, Kiyosu-shi (JP); Yoshitaka KURAOKA, Okazaki-shi (JP)

(21) Appl. No.: 18/796,750

(22) Filed: Aug. 7, 2024

Related U.S. Application Data
(63) Continuation of application No. PCT/JP2022/033904, filed on Sep. 9, 2022.

(30) Foreign Application Priority Data
Feb. 18, 2022 (JP) 2022-023766

(51) Int. Cl. C30B 29/40; C30B 25/18

(52) U.S. Cl. CPC C30B 29/40; C30B 25/18

(57) ABSTRACT

An object is to maintain excellent property of an epitaxial growth layer, even when the epitaxial growth layer on a group 13 nitride single crystal substrate in thinned. A group 13 nitride single crystal substrate is composed of a group 13 nitride single crystal and has a first main face and a second main face. The group 13 nitride single crystal substrate 2 contains zinc as a dopant, and the first main face has an off-angle of 0.4° or more and 1.0° or less.

### CROSS-REFERENCE TO RELATED APPLICATIONS

This application is a continuation application of PCT/JP2022/033904, filed Sep. 9, 2022, which claims priority to Japanese Application No. JP2022-023766 filed on Feb. 18, 2022, the entire contents all of which are incorporated hereby by reference.

### TECHNICAL FIELD

The present invention is related to a group 13 nitride single crystal substrate, substrate for deposition of an epitaxial growth layer, laminate and epitaxial substrate for a semiconductor element.

### BACKGROUND ART

Nitride semiconductor devices have been widely applied for optical devices as well as electronic devices such as a high electron mobility transistor (HEMT). For example, it is known an epitaxial substrate including a buffer layer, channel layer and barrier layer formed on a free-standing substrate composed of semi-insulating gallium nitride single crystal doped with zinc. Further, it is disclosed that the free-standing substrate is a gallium nitride single crystal substrate doped with zinc and having the orientation of (0001) plane, having a specific resistance at room temperature of 1×10² Ωcm or higher and semi-insulating property (Patent document 1).

### PRIOR TECHNICAL DOCUMENTS

### Patent Documents

(Patent document 1) Japanese patent No. 6705831B

### SUMMARY OF THE INVENTION

In the case that an epitaxial substrate composed of a semi-insulating GaN substrate is applied in, for example, a device operating in a high frequency band of several tens GHz or higher, It is preferred to reduce the film thickness of the channel layer, for example, to a thickness of 300 nm or smaller, for preventing the deterioration of properties of the channel layer. However, as the film thickness of the epitaxial growth layer on the semi-insulating zinc-doped gallium nitride substrate, as described in patent document 1, is reduced, it is found that the electron mobility (sheet carrier density) or mobility of secondary electron gas is reduced.

An object of the present invention is to maintain excellent property of an epitaxial growth layer even when the epitaxial growth layer on a group 13 nitride single crystal substrate is thinned.

The present invention provides a group 13 nitride single crystal substrate comprising a group 13 nitride single crystal and having a first main face and a second main face, wherein said group 13 nitride single crystal comprises zinc as a dopant and wherein said first main face has an off-angle of 0.4° or more and 1.0° or less.

Further, the present invention provides a substrate for depositing an epitaxial growth layer, said substrate comprising said group 13 nitride single crystal substrate, wherein said first main face comprises an epitaxial growth surface.

Further, the present invention provides a composite substrate for depositing an epitaxial growth layer, said composite substrate comprising the substrate for depositing the epitaxial growth layer, and an underlying substrate laminated with said group 13 nitride single crystal substrate.

Further, the present invention provides a laminate comprising:
said substrate for depositing an epitaxial growth layer, and
said epitaxial growth layer on said first main face.

Further, the present invention provides an epitaxial substrate for a semiconductor element, said epitaxial substrate comprising:
said substrate for depositing said epitaxial growth layer,
a buffer layer on said first main face,
a channel layer on said buffer layer, and
a barrier layer on said channel layer.

According to the present invention, in a group 13 nitride single crystal substrate composed of a group 13 nitride single crystal substrate and having a first main face and second main face, the excellent property of the epitaxial growth substrate can be maintained, even when the thickness of the epitaxial growth layer on the group 13 nitride single crystal substrate is reduced.

For example, it is found that the reduction of the sheet carrier density and mobility of secondary electron gas can be suppressed, even when the thickness of the channel layer is made 300 nm or smaller, for example.

### BRIEF DESCRIPTION OF THE DRAWINGS

FIG. 1A is a schematic view showing an epitaxial substrate 1 for a semiconductor element according to an embodiment of the present invention, and FIG. 1B is a schematic view showing a composite substrate 8 for depositing an epitaxial growth layer.

FIG. 2A is a representative and schematic perspective view showing a group 13 nitride single crystal substrate 100 according to a preferred embodiment, and FIG. 2B is a diagram schematically illustrating the plane orientation and crystalline plane of crystalline structure of the group 13 nitride single crystal substrate according to a preferred embodiment.

FIG. 3 is a graph showing the dependency of the sheet carrier density of an epitaxial growth layer on the off-angle of a zinc-doped group 13 nitride single crystal substrate.

FIG. 4 is a graph showing the dependency of the carrier mobility of the epitaxial growth layer on the off-angle of a zinc-doped group 13 nitride single crystal substrate.

FIG. 5 is a photograph showing surface morphology of a channel layer in the case that the off-angle of a first main face of a zinc-doped group 13 nitride single crystal substrate is 0.66°.

FIG. 6 is a photograph showing surface morphology of a channel layer in the case that the off-angle of a first main face of a zinc-doped group 13 nitride single crystal substrate is 0.09°.

FIG. 7 is a photograph showing surface morphology in the case that the off-angle of a first main face of a zinc-doped group 13 nitride single crystal substrate is 1.15°.

FIG. 8 is a graph showing an example of relationship between the off-angle of a first main face of a zinc-doped group 13 nitride single crystal substrate and carbon concentration of a channel layer.

### MODES FOR CARRYING OUT THE INVENTION

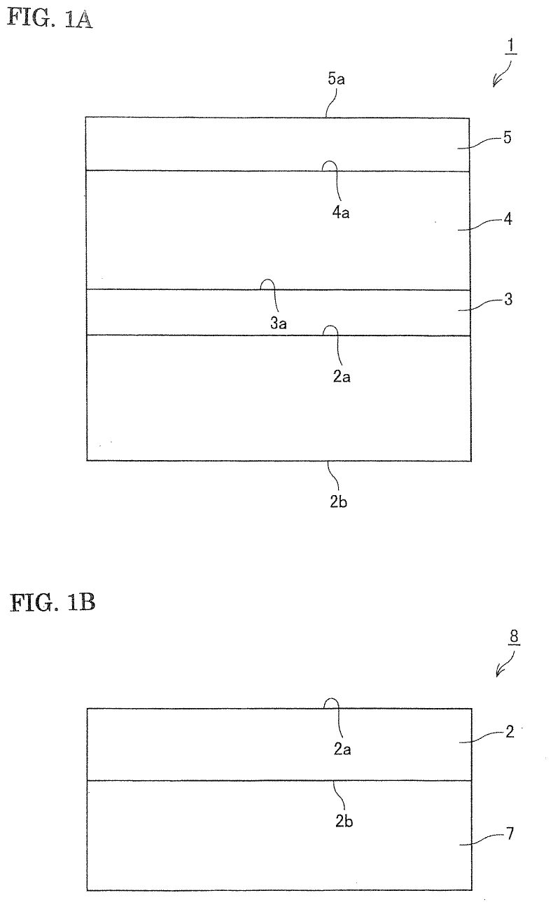

FIG. 1A is a schematic view showing an epitaxial substrate 1 for a semiconductor element according to an embodiment of the present invention.

A group 13 nitride single crystal substrate 2 has a first main face 2a and second main face 2b. The first main face 2a of the group 13 nitride single crystal substrate 2 is selected as a film-forming face, and an epitaxial growth layer is deposited on the first main face 2a. Specifically, according to the present invention, a buffer layer 3 is formed on the first main face 2a of the group 13 nitride single crystal substrate 2, a channel layer 4 is formed on the main face 3a of the buffer layer 3, and a barrier layer 5 is formed on the main face 4a of the channel layer 4. A predetermined electrode or the like may be formed on the main face 5a of the barrier layer 5.

A group 13 nitride single crystal substrate 2 is composed of a group 13 nitride single crystal and has a first main face 2a and second main face 2b.

The group 13 element is a group 13 element defined in IUPAC, and may particularly preferably be gallium, aluminum and/or indium. Further, the group 13 nitride single crystal may preferably be a group 13 nitride single crystal selected from gallium nitride, aluminum nitride, indium nitride or the mixed crystals thereof. More specifically, GaN, AlN, InN, GaₓAl₁₋ₓN (1>x>0), GaₓIn₁₋ₓN (1>x>0), AlₓIn₁₋ₓN (1>x>0) and GaₓAl_{y}In_{z}N (1>x>0, 1>y>0, x+y+z=1) are listed.

The definition of the single crystal will be described. Although it is included a single crystal, described in textbooks, in which atoms are regularly arranged over the whole of the crystal, it is not meant to be limited to only such mode and it is meant to include single crystals generally supplied in the industry. That is, the crystal may contain some degree of defects, or deformation may be inherent, or an impurity may be incorporated.

Further, the group 13 nitride single crystal substrate may be a free-standing substrate. The term “free-standing substrate” means a substrate that are not deformed or broken under its own weight during handling and can be handled as a solid. The free-standing substrate of the present invention can be used as a substrate for various types of semiconductor devices such as light emitting devices.

According to a preferred embodiment, the thickness of the free-standing substrate after the polishing may preferably be 300 μm or larger and preferably be 1000 μm or smaller.

Although the size of the free-standing substrate is not particularly limited, the size is preferably 2 inches, 4 inches or 6 inches and may be 8 inches or larger.

Further, as shown in FIG. 1B, an underlying substrate 7 composed of a material, whose thermal conductivity is higher than that of a group 13 nitride single crystal, is directly bonded to the side of the second main face 2b of the group 13 nitride single crystal substrate 2, so that a composite substrate 8 for depositing an epitaxial growth layer is obtained. The material of such underlying substrate may preferably be SiC, AlN or diamond. Further, the thermal conductivity of the underlying substrate may preferably be 200 W/m·K or higher and more preferably be 500 W/m·K or higher.

The group 13 nitride single crystal contains zinc as a dopant. On the viewpoint of the present invention, the concentration of zinc in the group 13 nitride single crystal may preferably be 1×10¹⁸ atoms/cm³ to 1×10²¹ atoms/cm³ and more preferably be 1×10¹⁹ atoms/cm³ to 1×10²¹ atoms/cm³. Further, the concentration of zinc in the group 13 nitride single crystal is to be measured by SIMS (Secondary ion mass spectrometry).

Further, the group 13 nitride single crystal may contain an element in addition to the dopant. The element may be, for example, hydrogen (H), oxygen (O), silicon (Si) or the like.

The off-angle of the first main face of the group 13 nitride single crystal substrate is made 0.4° or more and 1.0° or less. Here, the standard axis of the off-angle may be a-axis, c-axis or m-axis of the Wurtzite structure.

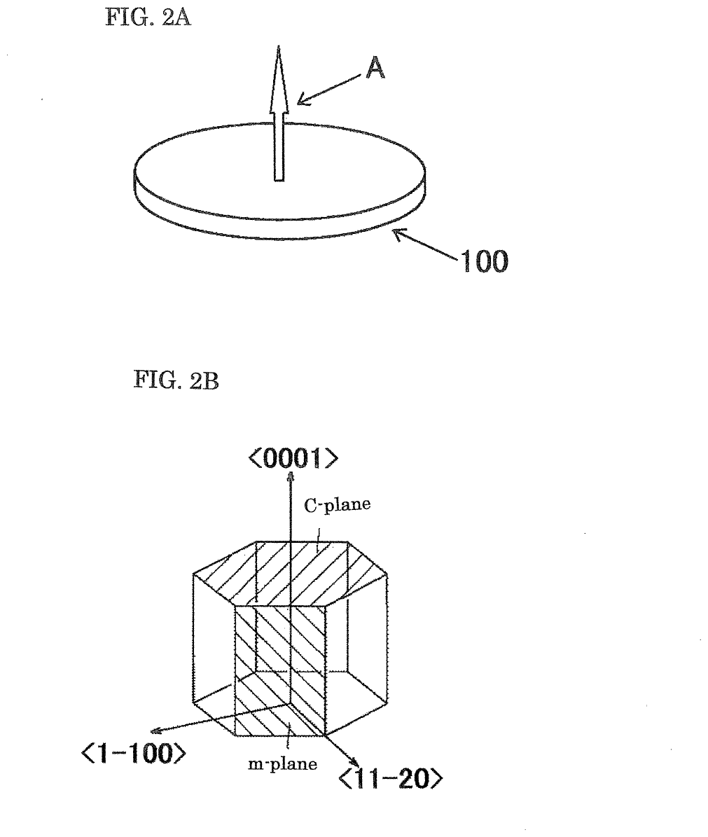

FIG. 2A is a representative and schematic perspective view showing a group 13 nitride single crystal substrate 100 according to a preferred embodiment. As shown in FIG. 2A, according to the group 13 nitride single crystal substrate 100 of the embodiment, the plane orientation <0001> (c axis) is inclined with respect to the normal vector A of the first face. That is, the group 13 nitride single crystal substrate 100 of the present embodiment is an off-angle substrate having an off-angle inclined with respect to the plane orientation <0001>.

FIG. 2B is a diagram schematically illustrating the plane orientation and crystal plane of the crystalline structure of the group 13 nitride single crystal substrate according to a preferred embodiment. In the crystalline structure shown in FIG. 2B, <0001> orientation is the orientation of the c-axis, <1-100> orientation is the orientation of the m-axis, and <11-20> orientation is the orientation of the a-axis. The upper face of the hexagonal crystal deemed as a regular hexagonal prism corresponds with the c-plane and the side wall face of the regular hexagonal prism corresponds with the m-plane.

According to the group 13 nitride single crystal substrate of the present embodiment, the c-plane is inclined with respect to the orientation of the first face. In other words, according to the group 13 nitride single crystal substrate of the present embodiment, the <0001> orientation (orientation of the c-axis) is inclined with respect to the normal vector of the first face (normal vector ‘′A’′ shown in FIG. 2A). The direction of the inclination may be the in a-axis or c-axis.

By making the off-angle 0.4° or more, the reduction of the property of the epitaxial growth layer can be suppressed even in the case that the epitaxial growth layer is thinned, and particularly the reduction of the sheet carrier density and mobility of secondary electron gas can be suppressed. On such viewpoint, the off-angle may more preferably be 0.5° or more. Further, in the case that the off-angle exceeds 1.0°, step bunching is generated in micro regions on the surface of the epitaxial growth layer, and distortion at an interface between epitaxial layers, for example at an interface between barrier layer and channel layer, is changed so that the reduction of the property, particularly reduction of the sheet carrier density is observed. On the viewpoint, the off-angle is made 1.0° or less, may preferably be made 0.9° or less, and more preferably be 0.7° or less on the viewpoint of both of the sheet carrier density and carrier mobility.

According to a preferred embodiment, the group 13 nitride single crystal substrate has a specific resistance at room temperature of 1×10⁷ Ωcm or higher. That is, the group 13 nitride single crystal substrate is of semi-insulating. On such viewpoint, the specific resistance at room temperature of the group 13 nitride single crystal substrate may more preferably be 1×10⁹ Ωcm or higher. Further, the specific resistance at room temperature of the group 13 nitride single crystal substrate is 1×10¹³ Ωcm or lower in many cases.

### (Production of Group 13 Nitride Single Crystal Substrate)

The method of producing the group 13 nitride single crystal substrate may be a vapor phase method such as Metal Organic Chemical Vapor Deposition (MOCVD) method, hydride vapor phase epitaxy (HVPE) method, pulse-excited deposition (PXD) method, MBE method, sublimation method or the like, or a liquid phase method such as ammonothermal method, flux method or the like. More preferably, the group 13 nitride single crystal is that produced by flux method.

In the case of flux method, it is preferred to provide a seed crystal film on the surface of a supporting substrate such as sapphire, a group 13 nitride single crystal or the like and to grow the group 13 nitride single crystal thereon by flux method.

AlxGa1-xN (0≤x≤1) or InxGa1-xN (0≤x≤1) may be listed as preferred examples as the material of the seed crystal film, and gallium nitride is particularly preferred.

The method of forming the seed crystal film may preferably be a vapor phase deposition method, and Metal Organic Chemical Vapor Deposition (MOCVD) method, hydride vapor phase deposition (HVPE) method, pulse-excited deposition (PXD) method, MBE method and sublimation method are listed. Metal Organic Chemical Vapor Deposition method is most preferred. Further, the growth temperature may preferably 950 to 1200° C.

In the case that the group 13 nitride single crystal is grown by flux method, the kind of the flux is not particularly limited, as far as the single crystal can be generated. According to a preferred embodiment, the flux contains at least one of an alkali metal and alkaline earth metal and the flux containing sodium metal is particularly preferred.

A raw material substance of a metal is mixed with the flux and applied. The raw material substrate of a metal may be a single metal, alloy or metal compound, and the single metal is preferred on the viewpoint of handling.

The growth temperature and holding time for the growth of the group 13 nitride single crystal by flux method are not particularly limited and may be appropriately changed depending on the composition of the flux. For example, in the case that gallium nitride crystal is grown by applying the flux containing sodium or lithium, the growth temperature may preferably be 800 to 950° C. and more preferably be 850 to 900° C.

According to flux method, the group 13 nitride single crystal is grown under atmosphere containing a gas including nitrogen atom. The gas may preferably be nitrogen gas and may be ammonia. Although the pressure of the atmosphere is not particularly limited and may preferably be 10 atoms or higher and more preferably be 30 atoms or higher on the viewpoint of preventing the evaporation of the flux. However, as the pressure is higher, the scale of the system becomes larger. Thus, the total pressure of the atmosphere may preferably be 2000 atoms or lower and more preferably be 500 atoms or lower. Although the gas other than the gas including nitrogen atom in the atmosphere is not limited, an inert gas is preferred, and argon, helium or neon is particularly preferred.

According to a particularly preferred embodiment, an MOCVD-GaN template is mounted in a crucible, and 10 to 60 mass parts of Ga metal, 15 to 90 mass parts of Na metal, 0.1 to 5 mass parts of Zn metal and 10 to 500 mg of C are then filled in the crucible. The crucible is contained in a heating furnace, the temperature in the furnace is made 800° C. to 950° C., the pressure in the furnace is made 3 MPa to 5 MPa, the heating is performed for 20 hours to 400 hours and the temperature is then cooled to room temperature. After the termination of the cooling, the crucible is drawn out of the furnace.

The thus obtained gallium nitride single crystal is polished with diamond abrasives to flatten the surface. The gallium nitride single crystal is thereby formed on the MOCVD-GaN template.

### (Formation of Epitaxial Growth Layer)

As the epitaxial growth layer grown on the group 13 nitride single crystal substrate, gallium nitride, aluminum nitride, indium nitride or the mixed crystals thereof are exemplified. Specifically, GaN, AlN, InN, GaₓAl₁₋ₓN (1>x>0), GaₓIn₁₋ₓN (1>x>0), AlₓIn₁₋ₓN (1>x>0) or GaₓAl_{y}In_{z}N (1>x>0, 1>y>0, x+y+z=1) are listed. Further, as a functional layer provided on the group 13 nitride single crystal substrate, a rectifying element layer, switching element layer or the like may be listed in addition to a light-emitting layer.

According to a preferred embodiment, for example as shown in FIG. 1A, a buffer layer 3, channel layer 4 and barrier layer 5 are formed on a first main face 2a of a group 13 nitride single crystal substrate 2.

The formation of the buffer layer 3, channel layer 4 and barrier layer 5 can be performed by, for example, metal organic chemical vapor deposition (MOCVD) method. According the formation of the layers with MOCVD method, metal organic raw material gases (TMG (trimethyl gallium), TMA (trimethyl aluminum), TMI (trimethyl indium) or the like) depending on the target composition, ammonia gas, hydrogen gas and nitrogen gas are supplied into a reactor of an MOCVD furnace, and the group 13 nitride single crystal is subsequently generated by the vapor phase reaction of the metal organic raw material gases corresponding with the respective layers and ammonia gas while the group 13 nitride single crystal substrate mounted in the reactor is heated at a predetermined temperature.

The preferred growth condition of each layer by MOCVD method is as follows.

### (Buffer Layer)

Temperature for formation: 700° C. to 1200° C.

Pressure in reactor: 5 kPa to 30 kPa

Carrier gas: Hydrogen

Ratio of nitrogen gas/raw material gas for group 13 element: 5000 to 20000

Ratio of raw material gas for aluminum/raw material gas for group 13 element: 0.7 to 1.0

### (Channel Layer)

Temperature for formation: 950° C. to 1200° C.

Pressure in reactor: 30 kPa to 105 kPa

Carrier gas: Hydrogen

Ratio of nitrogen gas/raw material gas for group 13 element: 1000 to 10000

(Barrier Layer: When it is Formed with AlGaN)

Temperature for formation: 1000° C. to 1200° C.

Pressure in reactor: 1 kPa to 30 kPa

Ratio of nitrogen gas/raw material gas for group 13 element: 5000 to 20000

Carrier gas: Hydrogen

Ratio of raw material gas for aluminum/raw material gas for group 13 element: 0.1 to 0.4

### (Barrier Layer: When it is Formed of InAlN)

Temperature for formation: 700° C. to 900° C.

Pressure in reactor: 1 kPa to 30 kPa

Ratio of nitrogen gas/raw material gas for group 13 element: 2000 to 20000

Carrier gas: Nitrogen

Ratio of raw material gas for indium/raw material gas for group 13 element: 0.1 to 0.9

### (Barrier Layer: When it is Formed of InAlGaN)

Temperature for formation: 700° C. to 1000° C.

Pressure in reactor: 1 kPa to 30 kPa

Ratio of nitrogen gas/raw material gas for group 13 element: 2000 to 20000

Carrier gas: Nitrogen

Ratio of raw material gas for aluminum/raw material gas for group 13 element: 0.1 to 0.9

Ratio of raw material gas for indium/raw material gas for group 13 element: 0.1 to 0.9

According to a preferred embodiment, the thickness of the epitaxial growth layer is 300 nm or smaller and may preferably be 260 nm or smaller. Further, although the lower limit of the thickness of the epitaxial growth layer is not particularly limited, the thickness is normally 50 nm or larger in many cases. Further, according to a more preferred embodiment, the thickness of the channel layer is 300 nm or smaller and preferably 260 nm or smaller.

According to a preferred embodiment, carbon concentration contained in the epitaxial growth layer is preferably lower. In this case, the concentration of carbon in the epitaxial growth layer may preferably be 5×10¹⁶ atom/cm³ or lower and more preferably be 2×10¹⁶ atom/cm³ or lower. Further, the concentration of carbon in the epitaxial growth layer is to be measured by SIMS (Secondary ion mass spectroscopy).

### Examples

### (Production of Gallium Nitride Single Crystal Substrate)

### (Production of Seed Crystal Substrate)

A seed crystal film having a thickness of 2 μm and composed of gallium nitride was deposited by MOCVD method on a surface of a c-plane sapphire substrate (underlying substrate) having a diameter of 2 inches, to obtain an MOCVD-GaN template which can be applied as a seed crystal substrate. At this time, the off-angle of the surface of the c-plane sapphire substrate was appropriately adjusted, so that the off-angle at the surface of the seed crystal film was made 0 to 1.2°.

### (Growth of Zinc-Doped Gallium Nitride Single Crystal by Na Flux Method)

By applying the template obtained as described above was applied as the seed crystal substrate and Na flux method, a zinc-doped gallium nitride single crystal was formed. Specifically, 30 g of Ga metal, 45 g of Na metal, 1 g of Zn metal and 100 mg of C were filled in an alumina crucible, respectively, and the crucible was closed with an alumina lid. The crucible was contained in a heating furnace, the temperature in the furnace was made 850° C., the pressure in the furnace was made 4.5 MPa, and the heating was performed over 100 hours, followed by cooling to room temperature. After the termination of cooling, the alumina crucible was drawn out of the furnace to prove that brown gallium nitride single crystal was deposited in a thickness of about 1000 μm on the surface of the seed crystal substrate.

### (Flattening of Surface)

The thus obtained gallium nitride single crystal was polished with diamond abrasives so that the surface is flattened and the total thickness of the gallium nitride single crystal formed on the underlying substrate was made 700 μm. As the thus obtained underlying substrate and gallium nitride single crystal were observed by eyes, cracks were not confirmed in all of them.

### (Separation of Seed Crystal Substrate)

The seed crystal substrate was separated from the gallium nitride single crystal by laser lift-off method to obtain a gallium nitride single crystal substrate.

### (Polishing Treatment)

The first main face and second main face of the gallium nitride single crystal substrate were subjected to polishing treatment, respectively, to obtain a free-standing substrate having a thickness of 400 μm and composed of zinc-doped gallium nitride single crystal.

### (Measurement of Specific Resistance)

As the specific resistance of the zinc-doped gallium nitride single crystal was measured by capacitance method (“COREMA-WT” produced by SEMIMAP Corporation), it was obtained a value of 5×10⁷ to 1×10¹¹ Ω·cm.

### (Formation of Epitaxial Growth Layer)

The buffer layer 3, channel layer 4 and barrier layer 5 were subsequently formed by MOCVD method. The conditions for forming the respective layers were as follows.

### (Buffer Layer 3)

Material: AlN
Temperature for formation: 1050° C.
Pressure in reactor: 5 kPa
Ratio of nitrogen gas/raw material gas for aluminum (trimethyl aluminum): 15000
Ratio of raw material gas for aluminum/raw material gas for group 13 element: 1.0
Thickness: 20 nm

### (Channel Layer 4)

Material: GaN
Temperature for formation: 1050° C.
Pressure in reactor: 100 kPa
Ratio of nitrogen gas/raw material gas for gallium (trimethylgallium): 2000
Thickness: 200 nm

### (Barrier Layer)

Material: AlGaN
Temperature: 1050° C.
Pressure in reactor: 5 kPa
Ratio of nitrogen gas/raw material gas for group 13 element (trimethyl gallium and trimethyl aluminum): 12000
Ratio of raw material gas for aluminum/raw material gas for group 13 element: 0.25
Thickness: 25 nm

### (Production of Device for Measuring Hall Effect)

It was produced a device for measuring the sheet density and carrier mobility of the thus obtained epitaxial substrate for a semiconductor device. As the measuring device, a plurality of chips each having a square of 6 mm was cut out from an epitaxial substrate for a semiconductor device, and ohmic electrodes were formed near the ends at the four corners of the chip. 1 mm square of pattern composed of Ti/Al/Ni/Au was formed by vacuum vapor deposition method and photolithography as the electrode to provide the device for Hall measurement. The respective thicknesses of the metal layers of Ti, Al, Ni and Au may preferably be made in a range of 5 nm to 50 nm, a range of 40 nm to 400 nm, a range of 4 nm to 40 nm and a range of 20 nm to 200 nm in the order. Thereafter, it is preferred to perform heat treatment at 600° C. to 1000° C. under nitrogen atmosphere for 10 seconds to 1000 second, for improving the ohmic property of a source electrode and drain electrode.

### (Measurement of Sheet Carrier Density and Carrier Mobility)

The sheet carrier density and carrier mobility at room temperature of the epitaxial growth layer of the thus produced device for Hall measurement were measured with Hall effect measurement (van der Pauw method). The Hall measurement effect was measured with a Hall effect measuring system (“ResiTest 8300” produced by TOYO Corporation). The results of the measurement were shown in table 1.

### (Measurement of Off-Angle)

For investigating the relationship of the sheet carrier density, carrier mobility and off-angle of the first main face of the zinc-doped gallium nitride single crystal substrate of the Hall measurement device was measured by X-ray diffraction method. The X-ray diffraction measurement was performed by a multi-purpose X-ray diffraction system (“D8 DISCOVER” produced by Bruker AXS Corporation). The results of measurement of the respective examples were shown in table 1.

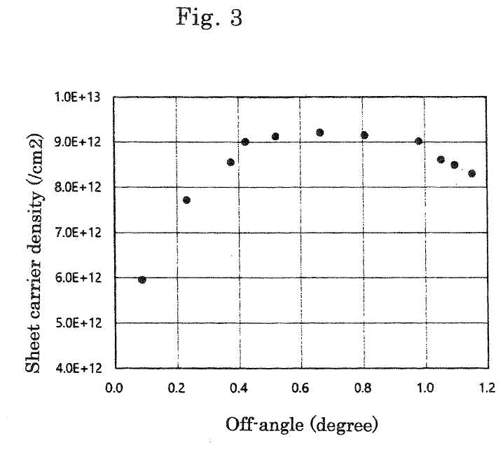

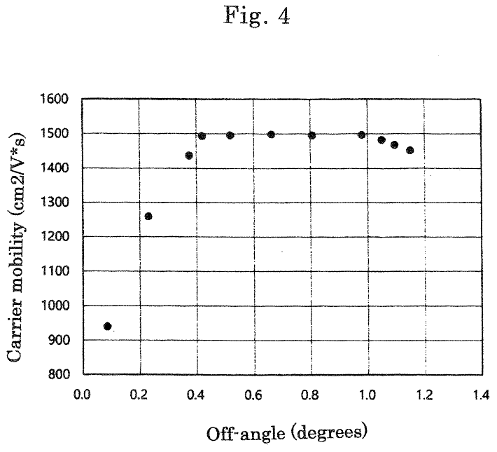

Further, the relationship of the off-angle and sheet carrier density was shown in FIG. 3, and the relationship of the off-angle and carrier mobility was shown in FIG. 4.

TABLE 1

| | Off-angle of | | |
|---|---|---|---|
| | substrate | Sheet carrier | Carrier mobility |
| | [degree] | density [/cm2] | [cm2/V*s] |
| Comparative | 1.15 | 8.30E+12 | 1452 |
| Example | | | |
| Comparative | 1.09 | 8.49E+12 | 1468 |
| Example | | | |
| Comparative | 1.05 | 8.61E+12 | 1482 |
| Example | | | |
| Inventive | 0.98 | 9.02E+12 | 1497 |
| Example | | | |
| Inventive | 0.81 | 9.15E+12 | 1495 |
| Example | | | |
| Inventive | 0.66 | 9.22E+12 | 1498 |
| Example | | | |
| Inventive | 0.52 | 9.13E+12 | 1496 |
| Example | | | |
| Inventive | 0.42 | 9.01E+12 | 1493 |
| Example | | | |
| Comparative | 0.37 | 8.56E+12 | 1437 |
| Example | | | |
| Comparative | 0.23 | 7.72E+12 | 1259 |
| Example | | | |
| Comparative | 0.09 | 5.95E+12 | 940 |
| Example | | | |

As can be seen from table 1, in the case that the off-angle of the first main face (epitaxial growth surface) of the zinc-doped gallium nitride single crystal substrate is in a range of 0.4 to 1.0°, the sheet carrier density and carrier mobility were proved to be high. On the contrary, in the case that the off-angle of the first main face of the zinc-doped gallium nitride single crystal substrate is below 0.4° or above 1.0°, the reduction of the sheet carrier density and carrier mobility were observed.

### (Evaluation of Surface Morphology)

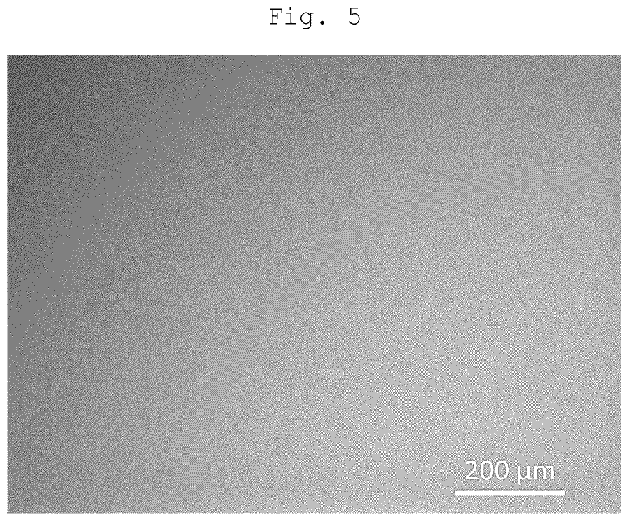

The surface morphology of the epitaxial growth layer was evaluated by an infinite interference optical microscope (“DM8000M” produced by LEICA Corporation). The magnification of observation was made 100 folds. As a result, according to the inventive examples in which the off-angles were 0.4° to 1.0°, good surface morphology with small roughness was confirmed. For example, FIG. 5 shows the surface morphology of the channel layer in the case that the off-angle of the first main face of the zinc-doped group 13 nitride single crystal substrate was 0.66°, and smooth surface morphology with small roughness can be observed.

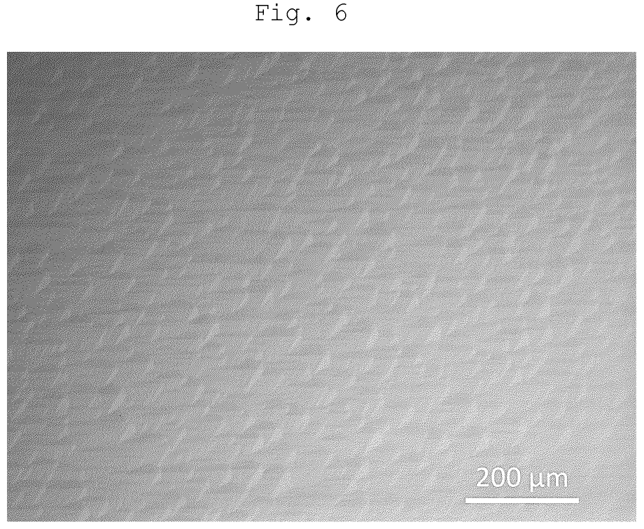

On the other hand, in the case that the off-angle of the first main face of the zinc-doped group 13 nitride single crystal substrate is below 0.4°, it was observed the morphology in which many island-shaped fine protrusions are dispersed. For example, FIG. 6 shows the surface morphology of the channel layer in the case that the off-angle was 0.09°.

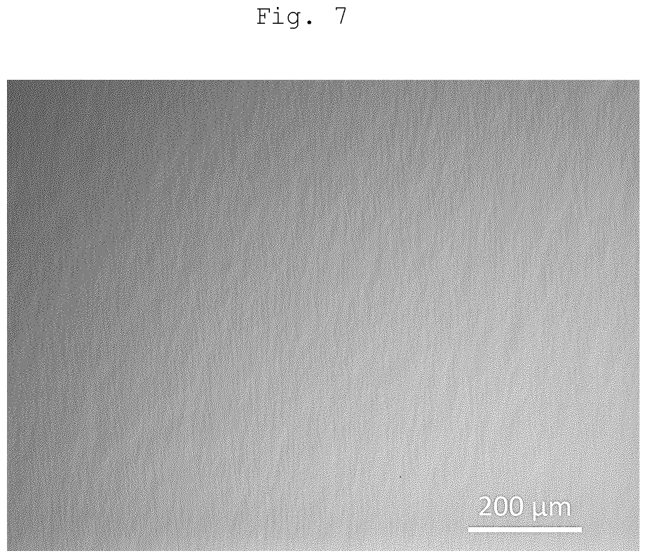

Further, in the case that the off-angle of the first main face of the zinc-doped group 13 nitride single crystal substrate exceeds 1.0°, so-called step bunching is generated. For example, FIG. 7 shows the surface morphology of the channel layer in the case that the off-angle is 1.15°, indicating that many fine and elongate steps are formed.

### (Evaluation of Carbon Concentration of Epitaxial Growth Layer)

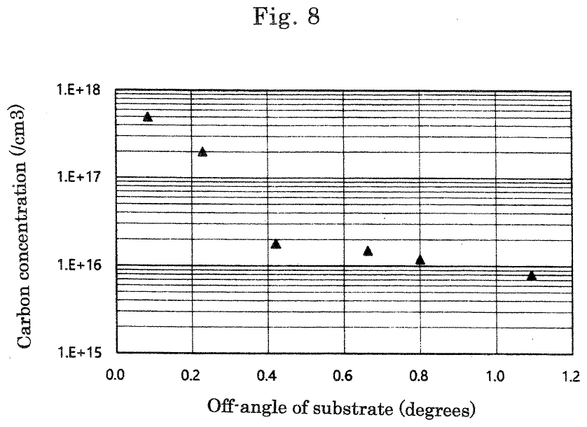

The carbon concentration of the channel layer was measured by SIMS (Secondary ion mass spectroscopy). FIG. 8 is a graph showing an example of relationship between the off-angle of the first main face of the zinc-doped group 13 nitride single crystal substrate and carbon concentration of the channel layer. In the case that the off-angle of the first main face of the zinc-doped group 13 nitride single crystal substrate was 0.4º to 1.0°, the carbon concentration of the channel layer was proved to be 2×10¹⁶/cm³ or lower. On the other hand, in the case that the off-angle was below 0.4°, it was observed an increase of carbon concentration of the channel layer.

The following interpretation may be given concerning the experimental results described above.

That is, in the case that the off-angle of the first main face of the zinc-doped group 13 nitride single crystal substrate is below 0.4°, the surface morphology of the channel layer is deteriorated and electrons of the secondary electron gas at an interface between a barrier layer and channel layer are scattered to reduce the carrier mobility. It is considered that electron traps are increased and sheet carrier density is further decreased due to the influences of the increase of the carbon concentration of the channel layer.

On the other hand, in the case that the off-angle of the first main face of the zinc-doped group 13 nitride single crystal substrate exceeds 1.0°, it is considered that the step bunching is generated on the surface of the channel layer so that the state of the deformation is changed at the interface of the barrier layer and channel layer and the sheet carrier density is reduced.

Thus, the off-angle of the first main face of the group 13 nitride single crystal substrate is made in a range of 0.4° to 1.0° so that good morphology is obtained on the surface of the channel layer and the increase of the carbon concentration of the channel layer is suppressed, resulting in good sheet carrier density and carrier mobility.

1. A group 13 nitride single crystal substrate comprising a group 13 nitride single crystal and having a first main face and a second main face,
wherein said group 13 nitride single crystal contains zinc as a dopant, and
wherein said first main face has an off-angle of 0.4° or more and 1.0° or less.

2. The group 13 nitride single crystal substrate of claim 1, wherein said group 13 nitride single crystal substrate has a specific resistance at room temperature of 1×10⁷ Ωcm or higher.

3. The group 13 nitride single crystal substrate of claim 1, wherein said group 13 nitride single crystal is produced by flux method.

4. The group 13 nitride single crystal substrate of claim 1, wherein said off-angle of said first main face is 0.5° or more and 0.7° or less.

5. A substrate for depositing an epitaxial growth layer, said substrate comprising said group 13 nitride single crystal substrate of claim 1, wherein said first main face comprises a surface subjected to epitaxial growth.

6. A composite substrate for depositing an epitaxial growth layer, said composite substrate comprising:
the substrate for depositing an epitaxial growth layer of claim 5; and
an underlying substrate laminated with said group 13 nitride single crystal substrate.

7. A laminate comprising:
the substrate for depositing an epitaxial growth layer of claim 5; and
an epitaxial growth layer on said first main face.

8. The laminate of claim 7, further comprising an underlying substrate laminated with said group 13 nitride single crystal substrate.

9. An epitaxial substrate for a semiconductor element, said epitaxial substrate comprising:
the substrate for depositing an epitaxial growth layer of claim 5;
a buffer layer on said first main face;
a channel layer on said buffer layer; and
a barrier layer on said channel layer.

10. The epitaxial substrate for a semiconductor element of claim 9, said epitaxial substrate further comprising an underlying substrate laminated with said group 13 nitride single crystal substrate.
